(19) United States
(12) Patent Application Publication
(10) Pub. No.: US 2025/0107303 A1
(43) Pub. Date: Mar. 27, 2025

(54) METHOD OF MANUFACTURING LIGHT-EMITTING DEVICE, AND LIGHT-EMITTING DEVICE

(71) Applicant: NICHIA CORPORATION, Anan-shi (JP)

(72) Inventors: Shinya MITSUHASHI, Tokushima-shi (JP); Takuhiro FURUKAWA, Komatsushima-shi (JP)

(73) Assignee: NICHIA CORPORATION, Anan-shi (JP)

(21) Appl. No.: 18/888,457

(22) Filed: Sep. 18, 2024

(30) Foreign Application Priority Data
Sep. 22, 2023 (JP) 2023-158360

(51) Int. Cl. H01L 33/62; H01L 25/075; H01L 33/60

(52) U.S. Cl. CPC H10H 20/857; H01L 25/0753; H10H 20/856; H10H 20/0363; H10H 20/0364

(57) ABSTRACT

A method of manufacturing a light-emitting device includes: preparing at least one first structure including a support substrate, an adhesive layer, and light-emitting elements each having a first surface, and a second surface, and comprising a pair of element electrodes disposed on a second surface side; preparing a second structure including a substrate including a base and a plurality of pairs of wirings, and a bonding member disposed between a pair of wirings of the plurality of pairs of wirings; obtaining a third structure by causing the pair of element electrodes to face the pair of wirings and bonding each of light-emitting elements to the substrate with the bonding member interposed therebetween in a state in which the light-emitting elements and the substrate are heated at a first temperature; heating the third structure at a second temperature equal to or higher than the first temperature; and removing the support substrate from the third structure.

### CROSS-REFERENCE TO RELATED APPLICATIONS

The present application claims priority under 35 U.S.C. § 119 to Japanese Patent Application No. 2023-158360, filed Sep. 22, 2023, the entire contents of which are hereby incorporated by reference.

### BACKGROUND

### 1. Technical Field

The present disclosure relates to a method of manufacturing a light-emitting device, and a light-emitting device.

### 2. Description of Related Art

Light-emitting devices in which light-emitting elements are mounted on a substrate are known. In a process of manufacturing such a light-emitting element, when a light-emitting element is transferred onto a base, for example, a step of forming a bonding member on the base; a step of preparing a light-emitting-element-mounted carrier substrate by disposing the light emitting element on a carrier substrate; a step of disposing the light-emitting-element-mounted carrier substrate on the bonding member such that the light-emitting element and the bonding member face each other; and a step of removing the carrier substrate from the light-emitting element are performed (see Japanese Patent Publication No. 2021-103774, for example).

### SUMMARY

It is an object of the present disclosure to provide a method of manufacturing a light-emitting device, in which high reliability in transferring a light-emitting element is ensured, and to provide a light-emitting device.

A method of manufacturing a light-emitting device according to one embodiment of the present disclosure includes: preparing a first structure including a support substrate, an adhesive layer disposed on a first main surface of the support substrate, and a plurality of light-emitting elements each having a first surface and a second surface that is located on a side opposite the first surface and has a pair of element electrodes disposed on the second surface side, the first surface being in contact with the adhesive layer; preparing a second structure including a substrate including a base and a plurality of pairs of wirings disposed on an upper surface of the base, and a bonding member disposed between a pair of wirings of the plurality of pairs of wirings and having a thickness greater than a thickness of each of the wirings; obtaining a third structure by causing the pair of element electrodes of the first structure to face the pair of wirings of the second structure, and by bonding each of the plurality of light-emitting elements to the substrate with the bonding member interposed therebetween in a state in which the plurality of light-emitting elements and the substrate are heated at a first temperature; heating the third structure at a second temperature equal to or higher than the first temperature; and removing the support substrate from the third structure.

Further, a light-emitting device according to one embodiment of the present disclosure includes: a substrate including a base and a plurality of pairs of wirings disposed on the base; a plurality of light-emitting elements each having a first surface and a second surface that is located on a side opposite the first surface and has a pair of element electrodes disposed on second surface side, the pair of element electrodes facing a pair of wirings of the plurality of pairs of wirings; and a first metal plating part and a second metal plating part, the first metal plating part and the second metal plating part electrically connecting the pair of element electrodes of each of the plurality of light-emitting elements to the pair of wirings. In a cross-sectional view taken through the first surface and the pair of element electrodes of each of the plurality of light-emitting elements, the first metal plating part has an upper surface in contact with the pair of element electrodes, a first lateral surface connected to one end of the upper surface and located closer to the second metal plating part, and a second lateral surface connected to another end of the upper surface and located opposite to the first lateral surface. In the cross-sectional view, a shape of the first lateral surface differs from a shape of the second lateral surface. In the cross-sectional view, the first lateral surface has a projection.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a cross-sectional view schematically illustrating a light-emitting device according to an embodiment.

FIG. 2A is a diagram (1) schematically illustrating an example of a manufacturing process in a method of manufacturing the light-emitting device according to the embodiment.

FIG. 2B is a diagram (2) schematically illustrating the example of the manufacturing process in the method of manufacturing the light-emitting device according to the embodiment.

FIG. 2C is a diagram (3) schematically illustrating the example of the manufacturing process in the method of manufacturing the light-emitting device according to the embodiment.

FIG. 2D is a diagram (4) schematically illustrating the example of the manufacturing process in the method of manufacturing the light-emitting device according to the embodiment.

FIG. 2E is a diagram (5) schematically illustrating the example of the manufacturing process in the method of manufacturing the light-emitting device according to the embodiment.

FIG. 2F is a diagram (6) schematically illustrating the example of the manufacturing process in the method of manufacturing the light-emitting device according to the embodiment.

FIG. 2G is a diagram (7) schematically illustrating the example of the manufacturing process in the method of manufacturing the light-emitting device according to the embodiment.

FIG. 2H is a diagram (8) schematically illustrating the example of the manufacturing process in the method of manufacturing the light-emitting device according to the embodiment.

FIG. 2I is a diagram (9) schematically illustrating the example of the manufacturing process in the method of manufacturing the light-emitting device according to the embodiment.

FIG. 3A is a plan view (1) schematically illustrating an example of a manufacturing process in a method of manufacturing light-emitting devices according to a modification of the embodiment.

FIG. 3B is a plan view (2) schematically illustrating the example of the manufacturing process in the method of manufacturing the light-emitting devices according to the modification of the embodiment.

FIG. 3C is a plan view (3) schematically illustrating the example of the manufacturing process in the method of manufacturing the light-emitting devices according to the modification of the embodiment.

### DETAILED DESCRIPTION

In the following, a manufacturing method according to an embodiment of the present disclosure and a light-emitting device obtained by the manufacturing method (hereinafter may be referred to as a “light-emitting device according to an embodiment”) will be described with reference to the accompanying drawings. In the following description, terms indicating specific directions and positions (for example, “upper,” “upward,” “lower,” “downward,” and other terms including these terms) are used as necessary. These terms are used to facilitate understanding of the present disclosure with reference to the drawings, and the technical scope of the present invention is not limited by the meaning of these terms. The same reference numerals appearing in a plurality of drawings refer to the same or similar portions or members.

Further, embodiments described below exemplify a light-emitting device and the like to embody the technical ideas of the present disclosure, and the present invention is not limited to the described embodiments. In addition, unless otherwise specified, the dimensions, materials, shapes, relative arrangements, and the like of components described below are not intended to limit the scope of the present disclosure thereto, but are described as examples. The contents described in one embodiment can be applied to other embodiments and modifications. The sizes, positional relationships, and the like of members illustrated in the drawings may be exaggerated for clearer illustration. Furthermore, in order to avoid excessive complication of the drawings, a schematic view in which some elements are not illustrated may be used, or an end view illustrating only a cut surface may be used as a cross-sectional view.

### Light-Emitting Device According to Embodiment

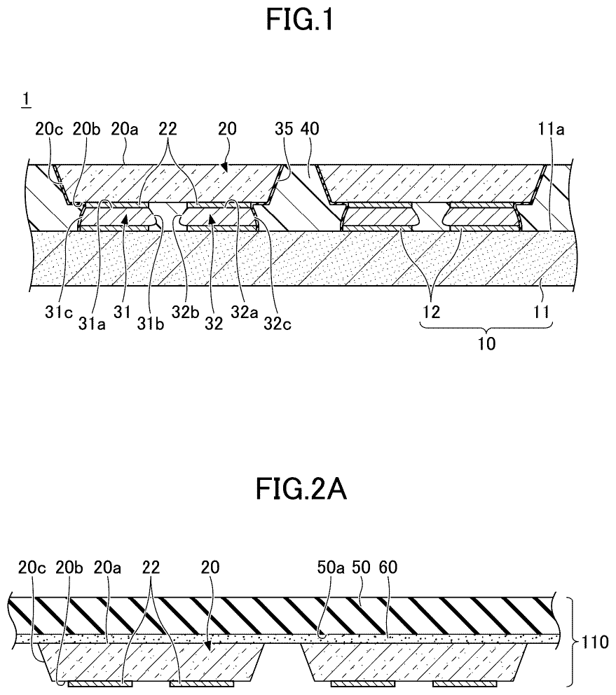

FIG. 1 is a cross-sectional view schematically illustrating a light-emitting device according to an embodiment. FIG. 1 illustrates a cross section taken through a first surface of a light-emitting element and a pair of element electrodes. As illustrated in FIG. 1, a light-emitting device 1 according to the present embodiment includes a substrate 10, a plurality of light-emitting elements 20, first metal plating parts 31, second metal plating parts 32, protective films 35, and a light reflective member 40. The light-emitting device 1 does not necessarily include the protective films 35. Further, the light-emitting device 1 does not necessarily include the light reflective member 40. In the light-emitting device 1, the plurality of light-emitting elements 20 are disposed on the substrate 10. For example, the plurality of light-emitting elements 20 are arranged in a matrix on the substrate 10.

The substrate 10 includes a flat plate-shaped base 11 and a plurality of pairs of wirings 12 disposed on the base 11. A pair of wirings 12 are arranged on an upper surface 11a of the base 11 so as to face each other at a predetermined interval. A light-emitting element 20 has a first surface 20a; a second surface 20b located opposite to the first surface 20a and having a pair of element electrodes 22 disposed thereon; and one or more lateral surfaces 20c connecting the first surface 20a and the second surface 20b. The pair of element electrodes 22 of the light-emitting element 20 are disposed so as to face the pair of wirings 12. The pair of wirings 12 may include three or more wirings as long as the pair of wirings 12 include an anode-side wiring and a cathode-side wiring. The pair of element electrodes 22 may include three or more electrodes as long as the pair of element electrodes 22 include an anode-side wiring and a cathode-side wiring.

The pair of element electrodes 22 of the light-emitting element 20 and the pair of wirings 12 of the substrate 10 are electrically connected to each other by a first metal plating part 31 and a second metal plating part 32. Specifically, one element electrode of the pair of element electrodes 22 and one wiring of the pair of wirings 12 are electrically connected to each other by the first metal plating part 31. The other element electrode of the pair of element electrodes 22 and the other wiring of the pair of wirings 12 are electrically connected to each other by the second metal plating part 32.

In the cross-sectional view illustrated in FIG. 1, the first metal plating part 31 has an upper surface 31a in contact with the one element electrode of the pair of element electrodes 22, a first lateral surface 31b connected to one end of the upper surface 31a and located on the side closer to the second metal plating part 32, and a second lateral surface 31c connected to the other end of the upper surface 31a and located opposite to the first lateral surface 31b. Further, the second metal plating part 32 has an upper surface 32a in contact with the other element electrode of the pair of the element electrodes 22, a first lateral surface 32b connected to one end of the upper surface 32a and located on the side closer to the first metal plating part 31, and a second lateral surface 32c connected to the other end of the upper surface 32a and located opposite to the first lateral surface 32b. A part of or the entirety of the upper surface 31a of the first metal plating part 31 may contact the one element electrode of the pair of element electrodes 22. Similarly, a part of or the entirety of the upper surface 32a of the second metal plating part 32 may contact the other element electrode of the pair of element electrodes 22.

The shape of the first lateral surface 31b differs from the shape of the second lateral surface 31c. The first lateral surface 31b has a projection projecting toward the second metal plating part 32. The second lateral surface 31c does not have a projection. The second lateral surface 31c may be, but is not necessarily, perpendicular to the upper surface 11a of the base 11. In the example of FIG. 1, the second lateral surface 31c is inclined toward the second metal plating part 32 as the second lateral surface 31c extends from the upper surface 11a of the base 11 toward the light-emitting element 20.

The shape of the first lateral surface 32b differs from the shape of the second lateral surface 32c. The first lateral surface 32b has a projection projecting toward the first metal plating part 31. The second lateral surface 32c does not have a projection. The second lateral surface 32c may be, but is not necessarily, perpendicular to the upper surface 11a of the base 11. In the example of FIG. 1, the second lateral surface 32c is inclined toward the first metal plating part 31 as the second lateral surface 32c extends from the upper surface 11a of the base 11 toward the light-emitting element 20.

A protective film 35 covers the second lateral surface 31c of the first metal plating part 31 and the second lateral surface 32c of the second metal plating part 32. The protective film 35 is, for example, a film containing silicon oxide or aluminum oxide. By providing the protective film 35, the possibility that the second lateral surface 31c and the second lateral surface 32c may be corroded due to a corrosive substance such as sulfur can be reduced. In the example of FIG. 1, the protective film 35 extends from the second lateral surface 31c and the second lateral surface 32c to an outer peripheral portion of the second surface 20b and the lateral surfaces 20c of the light-emitting element 20. The protective film 35 does not necessarily extend to the outer peripheral portion of the second surface 20b and the lateral surfaces 20c of the light-emitting element 20. Further, the protective film 35 may cover the first lateral surface 31b and the first lateral surface 32b in addition to the second lateral surface 31c and the second lateral surface 32c.

The light reflective member 40 is provided on the upper surface 11a of the base member 11, exposes the first surface 20a of the light-emitting element 20, and covers the second surface 20b and the lateral surfaces 20c. The light reflective member 40 may cover the lateral surfaces of the wirings 12, the lateral surfaces of the element electrodes 22, the first lateral surface 31b and the second lateral surface 31c of the first metal plating part 31, and the first lateral surface 32b and the second lateral surface 32c of the second metal plating part 32.

The light reflective member 40 covers the lateral surfaces 20c of the light-emitting element 20, and thus, light emitted from the lateral surfaces 20c the light-emitting element 20 is reflected by the light reflective member 40. Further, the light reflective member 40 covers the second surface 20b of the light-emitting element 20, and thus light traveling downward from the light-emitting element 20 is reflected by the light reflective member 40. Accordingly, the light extraction efficiency of the light-emitting device 1 can be improved. Further, the light reflective member 40 can clarify the boundary between a light emitting area and a non-light emitting area when light-emitting elements 20 are individually turned on. Accordingly, the contrast ratio between the light emitting area and the non-light emitting area can be improved.

As described above, in the light-emitting device 1, the first lateral surface 31b of the first metal plating part 31 has a projection and the second lateral surface 31c of the first metal plating part 31 does not have a projection. In the light-emitting device 1, there may be a case in which a corrosive substance such as airborne sulfur outside the light-emitting device 1 may enter the inside of the light-emitting device 1 during a manufacturing process or during use. In such a case, a corrosive substance such a sulfur first reaches the second lateral surface 31c located outward of the light-emitting element 20. Then, if the first plating portion 31 contains a metal such as copper that is corroded due to sulfur, corrosion occurs from the second lateral surface 31c of the first plating portion 31. For this reason, the protective film 35 may be formed on the surfaces (in particular, the second lateral surface 31c) of the first metal plating part 31. At this time, if a projection is provided on the second lateral surface 31c, there would be a possibility that a crack or a through hole would be formed in the protective film 35 due to the projection of the second lateral surface 31c when the first metal plating part 31 expands or contracts due to heat during the operation or the like of the light-emitting device 1. As a result, the first metal plating part 31 would be corroded by a corrosive substance such as sulfur. Conversely, in the light-emitting device according to the present disclosure, the second lateral surface 31c does not have a projection, and thus the second lateral surface 31c is less likely to contact a corrosive substance such as sulfur entering from the atmosphere. Therefore, the possibility that the first metal plating part 31 may be sulfided from the second lateral surface 31c side as a starting point can be reduced. The first lateral surface 31b is located in a region where the light-emitting element 20 and the substrate 10 face each other and is away from an entry path of a corrosive substance such sulfur, and thus the first lateral surface 31b is less likely to be sulfided. Therefore, the first lateral surface 32b may have a projection. In addition, by providing the first lateral surface 31b with a projection, the volume of the first metal plating part 31 increases as compared to when no projection is provided. As a result, the heat dissipation of the light-emitting device 1 can be improved. Although the first metal plating part 31 has been described above, the same applies to the second metal plating part 32.

The first lateral surface 31b of the first metal plating part 31 and the first lateral surface 32b of the second metal plating part 32 have projections facing each other, and the light reflective member 40 enters a space between the projections facing each other. Accordingly, an anchor effect is provided, and thus the adhesion between the light reflective member 40 and the first and second metal plating parts 31 and 32 can be improved.

Each component of the light-emitting device 1 will be described below.

### Substrate 10

The base 11 has, for example, a substantially rectangular shape in a plan view. As the base 11, a transparent base may be used, or an opaque base may be used. Examples of the material of the transparent base include glass, quartz, sapphire, ceramics (for example, transparent alumina), and organic films (for example, polyethylene terephthalate (PET)). Examples of the material of the opaque base include semiconductors (for example, Si, Ge, GaAs, and InP), ceramics (for example, alumina, aluminum nitride, and silicon nitride), and organic materials (for example, flame retardant type 4 (FR4)).

Each of the wirings 12 may be formed of, for example, a metal such as Cu, Ag, Au, Al, Pt, Ti, W, Pd, Fe, or Ni and/or an alloy containing one or more of these metals. A region on the upper surface 11a of the base 11 where the wirings 12 are not disposed may be, but is not necessarily, covered by an insulating film.

### Light-Emitting Element

The light-emitting element 20 has, for example, a substantially rectangular shape or a substantially square shape in a plan view. The light-emitting element 20 may have, for example, a square shape with a side of 40 μm or more and 100 μm or less in a plan view. In the light-emitting element 20, the first surface 20a and the second surface 20b are parallel to each other, for example. The lateral surfaces 20c may be perpendicular to the first surface 20a or may be inclined with respect to the first surface 20a. In the example of FIG. 1, opposite lateral surfaces 20c are inclined such that the width of the light-emitting element 20 decreases from the first surface 20a side toward the second surface 20b side in a cross-sectional view.

The light-emitting element 20 includes a semiconductor stack and the element electrodes 22 that are positive and negative electrodes disposed on the second surface 20b, which is the surface of the semiconductor stack. The light-emitting element 20 is flip-chip mounted on the substrate 10 such that the second surface 20b on which the element electrodes 22 are disposed faces the substrate 10. In this case, the first surface 20a opposite to the second surface 20b serves as a main light extraction surface of the light-emitting element 20.

In the light-emitting device 1, a plurality of light-emitting elements 20 may be two-dimensionally arranged in a matrix on the substrate 10. In this case, the plurality of light-emitting elements 20 can be arranged at predetermined intervals in the row and column directions. For example, the number of the light-emitting elements 20 included in the light-emitting device 1 can be 100 or more and 2,000,000 or less, preferably 1,000 or more and 500,000 or less, and more preferably 3,000 or more and 150,000 or less. By causing the light-emitting device 1 to include 100 or more light emitting elements, if the light-emitting device 1 is used for road surface projection of a vehicle headlight and the like, road surface projection including simple messaging and the like can be performed. Further, by causing the light-emitting device 1 to include 2,000,000 or less light emitting elements, a high-definition road surface projection can be achieved while reducing the size of the light-emitting device 1, and also light with sufficient illuminance can be emitted when the light-emitting elements 20 are individually turned on.

As a light-emitting element 20,
a light-emitting element that emits light having a given wavelength can be selected. For example, as a light-emitting element 20 that emits blue light or green light, a light-emitting element using a nitride semiconductor (InₓAl_{y}Ga_{1-x-y}N, 0≤x, 0≤y, x+y≤1) can be selected. Further, as a light-emitting element 20 that emits red light, a semiconductor represented by GaAlAs or AlInGaP can be used. Further, a semiconductor light-emitting element formed of any other material can be used. The composition and the emission color of a light-emitting element 20 to be used can be appropriately selected according to the purpose.

### First Metal Plating Part and Second Metal Plating Part

The first metal plating part 31 and the second metal plating part 32 may be formed by, for example, copper plating or gold plating. The first metal plating part 31 and the second metal plating part 32 may be formed of zinc (Zn), chromium (Cr), and/or nickel (Ni), for example. The thickness of each of the first metal plating part 31 and the second metal plating part 32 may be, for example, 3 μm or more and 10 μm or less.

### Light Reflective Member

For the light reflective member 40, a soft resin having relatively low elasticity and good shape conformability is preferably used. As the material of the light reflective member 40, a resin material having good transmissivity and insulating properties, for example, a thermosetting resin such as an epoxy resin or a silicone resin can be suitably used. Further, for the light reflective member 40, a white resin containing particles of a light reflective substance is preferably used as a base resin. Examples of the light reflective substance include titanium oxide, aluminum oxide, zinc oxide, barium carbonate, barium sulfate, boron nitride, aluminum nitride, and a glass filler.

### Method of Manufacturing Light-Emitting Device According to Embodiment

A method of manufacturing a light-emitting device according to an embodiment includes: a step of preparing a first structure including a support substrate, an adhesive layer disposed on a first main surface of the support substrate, and a plurality of light-emitting elements each having a first surface and a second surface that is located opposite to the first surface and has a pair of element electrodes disposed thereon, the first surface being in contact with the adhesive layer; a step of preparing a second structure including a substrate including a base and a plurality of pairs of wirings disposed on an upper surface of the base, and a bonding member disposed between a pair of wirings of the plurality of pairs of wirings and having a thickness greater than a thickness of each of the wirings; a step of obtaining a third structure by causing the pair of element electrodes of the first structure to face the pair of wirings of the second structure and bonding each of the plurality of light-emitting elements to the substrate with the bonding member interposed therebetween in a state in which each of the plurality of light-emitting elements and the substrate are heated at a first temperature; a step of heating the third structure at a second temperature equal to or higher than the first temperature; and a step of removing the support substrate from the third structure.

The method of manufacturing the light-emitting device according to the embodiment may further include, after the step of removing the support substrate, a step of forming metal plating that electrically connects the pair of element electrodes of each of the plurality of light-emitting elements to the pair of wirings of the substrate.

The method of manufacturing the light-emitting device according to the embodiment may further include, after the step of forming the metal plating, a step of removing the bonding member.

Each of the manufacturing steps of the method of manufacturing the light-emitting device according to the embodiment will be described below with reference to the drawings.

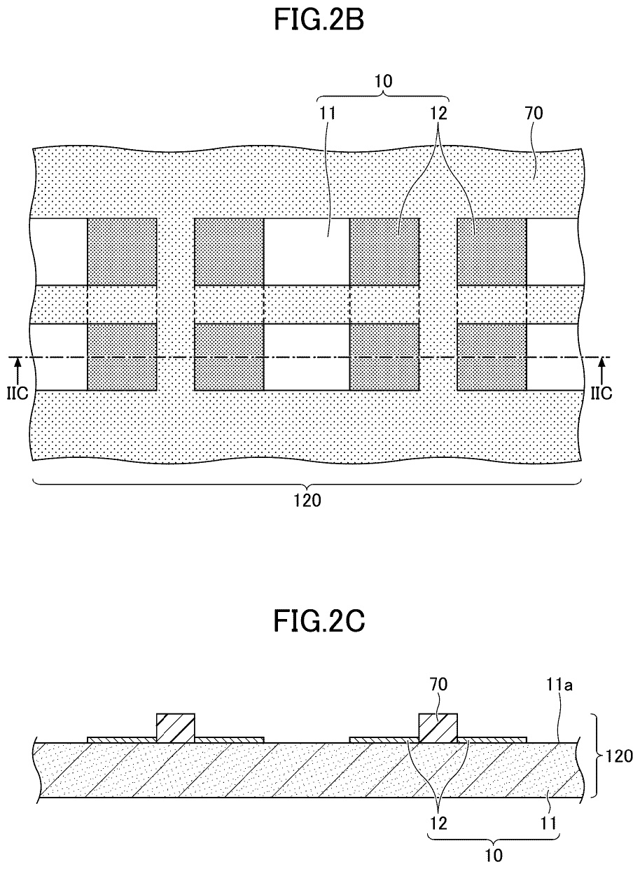

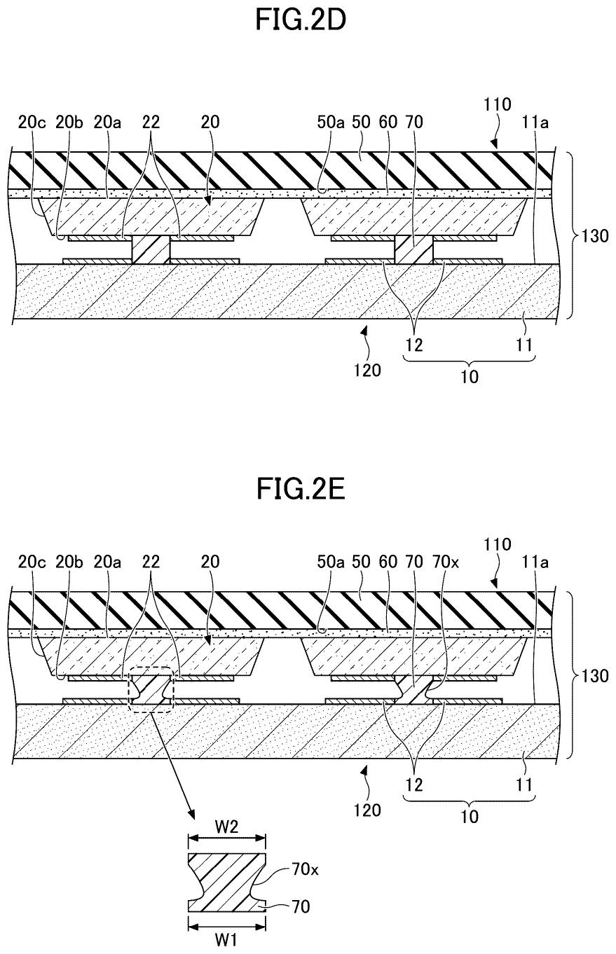

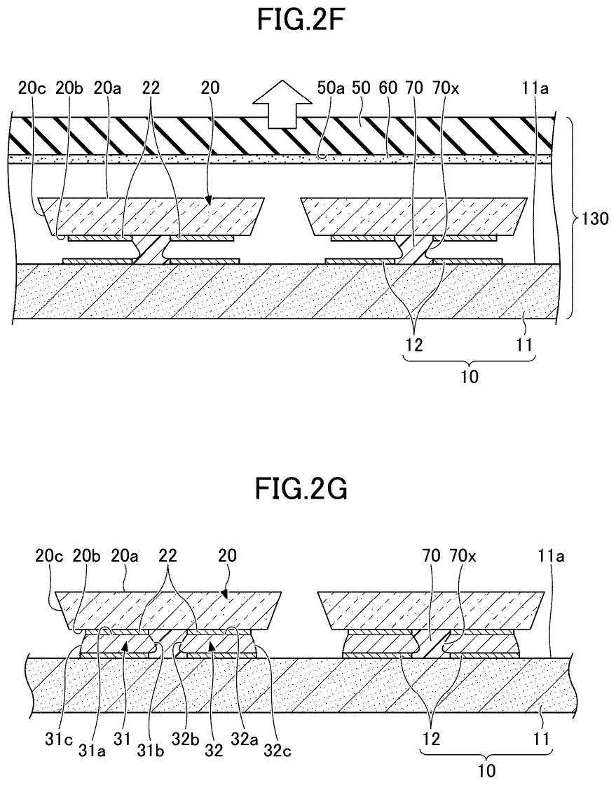

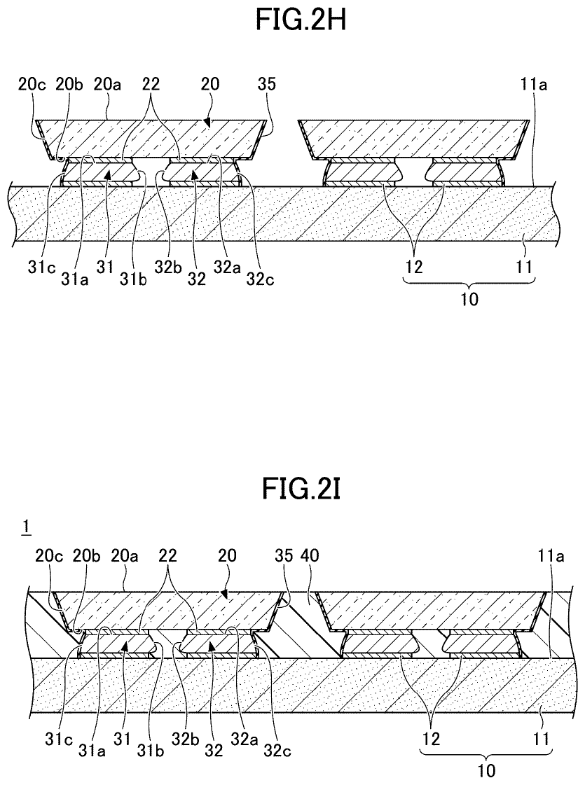

FIG. 2A to FIG. 2I are schematic diagrams illustrating an example of a manufacturing process in the method of manufacturing the light-emitting device according to the embodiment. Specifically, FIG. 2B is a plan view illustrating the manufacturing process of the light-emitting device. FIG. 2A and FIG. 2C to FIG. 2I are cross-sectional views illustrating the manufacturing process of the light-emitting device. In the description of the manufacturing method, preparing a member is not limited to manufacturing a member, and includes acquiring a member such as purchasing a member or receiving a member.

### Step of Preparing First Structure

First, as illustrated in FIG. 2A, a first structure 110 including: a support substrate 50; an adhesive layer 60 disposed on a first main surface 50a of the support substrate 50; and a plurality of light-emitting elements 20 each having a first surface 20a and a second surface 20b are prepared. The first surface 20a is in contact with the adhesive layer 60, and the second surface 20b is located opposite to the first surface 20a and has a pair of element electrodes 22 disposed thereon.

Specifically, first, the adhesive layer 60 is disposed on the first main surface 50a of the support substrate 50 by continuously applying an adhesive to the first main surface 50a of the support substrate 50. As the support substrate 50, for example, a glass substrate or the like can be used. As the adhesive, for example, at least one adhesive selected from the group consisting of a silicone-based adhesive, an epoxy-based adhesive, and an acrylic-based adhesive can be used.

Next, the plurality of light-emitting elements 20 are prepared, and each of the light-emitting elements 20 is bonded to the adhesive layer 60 such that the first surface 20a of each of the light-emitting elements 20 is in contact with the adhesive layer 60 on the support substrate 50. For example, 100 or more and 2,000,000 or less light-emitting elements 20 can be bonded to the adhesive layer 60 in a matrix. In this manner, the step of preparing the first structure 110 is completed.

### Step of Preparing Second Structure

Next, as illustrated in FIG. 2B and FIG. 2C, a second structure 120 including a substrate 10 and a bonding member 70 is prepared. The substrate 10 includes a base 11 and a plurality of pairs of wirings 12 arranged on an upper surface 11a of the base 11. The bonding member 70 is disposed between each pair of the plurality of pairs of wirings 12 on the upper surface 11a of the base 11, and has a thickness greater than the thickness of each of the wirings 12. FIG. 2C is a cross-sectional view taken through line IIC-IIC of FIG. 2B.

Specifically, first, the substrate 10 including the base 11 and the plurality of pairs of wirings 12 is prepared. The substrate 10 can be prepared by forming the plurality of pairs of wirings 12 on the upper surface 11a of the flat plate-shaped base 11 such as a silicon plate by plating, sputtering, vapor deposition or the like.

Next, the bonding member 70 is formed on the upper surface 11a of the base 11 such that the bonding member 70 is disposed between each pair of the plurality of pairs of wirings 12 and has a thickness greater than the thickness of each of the wirings 12. Specifically, the bonding member 70 having a planar size smaller than the planar size of a light-emitting element 20 in a cross-sectional view is formed in a region where the light-emitting element 20 is to be mounted, such that a pair of element electrodes 22 of the light-emitting element 20 and a corresponding pair of wirings 12 of the substrate 10 can face each other and can be spaced apart from each other when the light-emitting element 20 is to be mounted later.

The bonding member 70 can be formed by using photolithography or screen printing. Photolithography is preferable in that a fine pattern can be formed. The bonding member 70 preferably has adhesiveness. When the bonding member 70 has adhesiveness, the light-emitting element 20 to be mounted later can be bonded to and supported on the bonding member 70.

The bonding member 70 preferably has the above-described adhesiveness and also has chemical resistance against metal plating formed in the later step. For example, a phenol-based resin, an epoxy-based resin, a silicone-based resin, or an acrylic-based resin can be used as the bonding member 70. The bonding member 70 is, for example, a resist. When the bonding member 70 is used, it is not necessary to provide members suitable for the respective purposes of attaching and supporting the light-emitting element 20 and serving as a mask for plating bonding. Thus, the number of manufacturing steps can be reduced. Further, if different members are used, there would be restrictions due to a combination of formation conditions (for example, one solvent is dissolved in another solvent, or appropriate processing temperatures are different). Conversely, according to the present disclosure, the manufacturing process is not subjected to such restrictions and thus can be easily performed.

The shape of the bonding member 70 in a cross-sectional view may be a rectangular shape or a square shape. That is, the contact surface (upper surface) of the bonding member 70 in contact with the light-emitting element 20 is substantially perpendicular to the lateral surfaces of the bonding member 70. Accordingly, a contact region between the light-emitting element 20 and the bonding member 70 and a plating growth region where the wirings 12 of the substrate 10 and the element electrodes 22 of light-emitting element 20 are to be bonded to each other can be accurately secured.

The shape of the bonding member 70 in a cross-sectional view may be a tapered shape. The bonding member 70 can have a shape that becomes wider from the upper surface 11a of the base 11 toward the light-emitting element 20, or a shape that becomes narrower from the upper surface 11a of the base 11 toward the light-emitting element 20. If the bonding member 70 has a shape that becomes wider from the upper surface 11a of the base 11 toward the light-emitting element 20, the area where the light-emitting element 20 contacts the bonding member 70 can be increased, and thus the light-emitting element 20 and the bonding member 70 can be securely attached to each other.

By forming the bonding member 70 having a thickness greater than the thickness of each of the wirings 12, when the light-emitting element 20 is mounted on the bonding member 70 later, the wirings 12 provided on the base 11 and the element electrodes 22 of the light-emitting element 20 mounted on the bonding member 70 can be spaced apart from each other with the bonding member 70 interposed therebetween. The thickness of the bonding member 70 may be, for example, 5 μm or more and 20 μm or less.

### Step of Obtaining Third Structure

Next, as illustrated in FIG. 2D, a third structure 130 is obtained by causing the pair of element electrodes 22 of the first structure 110 to face the pair of wirings 12 of the second structure 120, and bonding the light-emitting element 20 to the substrate 10 with the bonding member 70 interposed therebetween in a state in which the light-emitting element 20 and the substrate 10 are heated at a first temperature.

Specifically, first, the second structure 120 is disposed on a stage with the pair of wirings 12 facing upward. Then, the first structure 110 is disposed on the second structure 120 such that the pair of element electrodes 22 face the pair of wirings 12. At this time, the upper surface of the bonding member 70 contacts the second surface 20b located between the pair of element electrodes 22. A portion of the upper surface of the bonding member 70 may cover end portions of the pair of element electrodes 22. The pair of element electrodes 22 of the light-emitting element 20 and the pair of wirings 12 of the substrate 10 are disposed spaced apart from each other.

Next, the light-emitting element 20 and the substrate 10 disposed on the stage are heated and pressurized at the first temperature. At this time, the light-emitting element 20 and the substrate 10 are subjected to thermocompression with the bonding member 70 interposed therebetween on the stage. That is, the bonding member 70 is softened, and the tack strength of the bonding member 70 allows the light-emitting element 20 and the substrate 10 to be bonded to each other with the bonding member 70 interposed therebetween, thereby obtaining the third structure 130. The first temperature is set to be equal to or higher than a temperature at which the bonding member 70 is softened. For example, if a temperature at which the bonding member 70 is softened is 90° C., the first temperature is preferably 95° C. or higher in consideration of a margin. Further, the heating time at the first temperature is preferably, for example, 1 minute or more and 1 hour or less. By performing heating under such conditions, the bonding member 70 can be softened to such an extent that the bonding member 70 exhibits a tack strength.

### Heating Third Structure at Second Temperature

Next, the third structure 130 is moved from the stage, and the third structure 130 is heated at a second temperature equal to or higher than the first temperature. FIG. 2E illustrates the third structure 130 after being heated at the second temperature. For example, an oven can be used to heat the third structure 130 at the second temperature. The second temperature is preferably equal to or higher than the first temperature and is 140° C. or lower. By setting the second temperature to be equal to or higher than the first temperature, the bonding member 70 can be sufficiently softened. By setting the second temperature to 140° C. or lower, if the wirings 12 and the element electrodes 22 contain copper, the possibility of oxidation of copper can be reduced.

In the step of obtaining the third structure, there may be a case in which the second structure 120 waits on the stage for a long period of time. In this case, a solvent volatilizes from the surface of the bonding member 70, and the tack strength on the surface side of the bonding member 70 is decreased. If the first structure 110 is disposed on the second structure 120 in this state, the bonding member 70 with reduced tack strength would fail to provide sufficient adhesion. In such a case, in the subsequent step of removing the support substrate from the third structure, there would be a possibility that the light-emitting element 20 would be peeled off from the bonding member 70 and taken away together with the support substrate 50.

By heating the bonding member 70 with reduced tack strength at the second temperature in this step, the adhesion between the light-emitting element 20 and the bonding member 70 can be improved as compared to that before the heating step at the second temperature. This is considered to be because the bonding member 70 is softened, the light-emitting element 20 is slightly embedded in the bonding member 70 by its own weight, and the light-emitting element 20 is brought into close contact with an inner portion of the bonding member 70 having higher tack strength than the surface of the bonding member 70.

When the third structure 130 is heated at the second temperature, the thickness of the bonding member 70 tends to be reduced. For example, the bonding member 70 having a thickness of 3 μm before being heated at the second temperature may be reduced in thickness by approximately 10%. When the thickness of the bonding member 70 is reduced, the thickness of the light-emitting device 1 can be reduced. Further, when the thickness of the bonding member 70 is reduced, the amount of metal plating used to form a first metal plating part 31 and a second metal plating part 32 in the step of forming metal plating described later can be reduced.

As illustrated in a partially enlarged view of FIG. 2E, a center portion of the bonding member 70 is recessed relative to the upper surface and the lower surface of the bonding member 70 in a cross-sectional view, thereby forming a recess 70x in the lateral surfaces of the bonding member 70. The recess 70x is formed in a shape having an acute-angled portion in a cross-sectional view, for example. The reason why the recess 70x is formed is that the bonding member 70 is softened by being heated at the second temperature and thus wets and spreads over the element electrodes 22 of the light-emitting element 20 and the wirings 12 of the substrate 10.

The wetting and spreading of the bonding member 70 is larger on the element electrode 22 side of the light-emitting element 20 than on the wiring 12 side of the substrate 10. Therefore, the ratio (W1/W2) of a width W2 of the upper surface of the bonding member 70 to a width W1 of the lower surface of the bonding member 70 after the heating step at the second temperature is greater than the ratio (W2/W1) before the heating step at the second temperature.

TABLE 1

| | | WIDTH | WIDTH | WIDTH OF |
|---|---|---|---|---|
| | | OF | OF | UPPER |
| | | UPPER | LOWER | SURFACE/ |
| WAITING | SECOND | SUR- | SUR- | WIDTH |
| ON | TEMPERATURE, | FACE | FACE | OF LOWER |
| STAGE | HEATING TIME | (mm) | (mm) | SURFACE |
| 0.5 HOURS | NO HEATING | 9.73 | 10.74 | 0.906 |
| | AT SECOND | | | |
| | TEMPERATURE | | | |
| | 95° C., 2 HOURS | 10.27 | 10.74 | 0.956 |
| | 110° C., 2 HOURS | 10.74 | 10.81 | 0.994 |
| | 130° C., 2 HOURS | 10.20 | 10.74 | 0.950 |

Table 1 indicates the results of actual measurements of the widths of the upper surface of the bonding member 70 and the widths of the lower surface of the bonding member 70. As an example, the time during which the second structure 120 waits on the stage was set to 0.5 hours (30 minutes), and a case in which the third structure was not heated at the second temperature, a case in which the second temperature was set to 95° C. and the third structure was heated at 95° C. for 2 hours, a case in which the second temperature was set to 110° C. and the third structure was heated at 110° C. for 2 hours, and a case in which the second temperature was set to 130° C. and the third structure was heated at 130° C. for 2 hours were examined.

As indicated in Table 1, it can be seen that the ratio of the width of the upper surface to the width of the lower surface in any of the cases where the third structure is heated at the second temperature is greater than the ratio of the width of the upper surface to the width of the lower surface in the case in which the third structure is not heated at the second temperature. Specifically, in a cross-sectional view, the ratio of the width of the upper surface to the width of the lower surface is less than 0.910 in the case in which the third structure is not heated at the second temperature, whereas the ratio of the width of the upper surface to the width of the lower surface is 0.910 or more in any of the cases where the third structure is heated at the second temperature. That is, the ratio of the width of the upper surface of the bonding member 70 to the width of the lower surface of the bonding member 70 after the step of heating the third structure at the second temperature is 0.910 or more.

Because the width W2 of the upper surface of the bonding member 70 increases as compared to that before the third structure is heated at the second temperature, the contact area between the upper surface of the bonding members 70 and the second surface 20b of the light-emitting element 20 increases, and as a result, the adhesion between the bonding member 70 and the light-emitting element 20 can be improved. Further, as indicated in Table 1, the width W1 of the lower surface of the bonding member 70 is not changed or increases as compared to that before the third structure is heated at the second temperature. That is, the contact area between the lower surface of the bonding member 70 and the base 11 after the third structure is heated at the second temperature is equal to or greater than the contact area between the lower surface of the bonding member 70 and the base 11 before the third structure is heated at the second temperature, and thus the adhesion between the bonding member 70 and the base 11 can be maintained or improved.

Step of Removing Support Substrate from Third Structure

Next, as illustrated in FIG. 2F, the support substrate 50 and the adhesive layer 60 are removed from the third structure 130. For example, the support substrate 50 and the adhesive layer 60 can be removed from the light-emitting element 20 by using an adsorption tool or the like to apply a force to the support substrate 50 in a direction indicated by the arrow of FIG. 2F, with the substrate 10 being fixed. In the step of heating the third structure at the second temperature, the adhesion between the light-emitting element 20 and the bonding member 70 is improved. Thus, in the step of removing the substrate, the interface between the second surface 20b of the light-emitting element 20 and the upper surface of the bonding member 70 is not peeled off, and the interface between the first surface 20a of the light-emitting element 20 and the lower surface of the adhesive layer 60 is peeled off. Accordingly, the possibility that the light-emitting element 20 is peeled off from the bonding member 70 and taken away together with the support substrate 50 can be reduced.

### Step of Forming Metal Plating

Next, after the step of removing the support substrate, metal plating is formed so as to electrically connect the pair of element electrodes 22 of the light-emitting element 20 to the pair of wirings 12 of the substrate 10 as illustrated in FIG. 2G. Accordingly, one of the pair of element electrodes 22 is electrically connected to one of the pair of wirings 12 via a first metal plating part 31, and the other of the pair of element electrodes 22 is electrically connected to the other of the pair of wirings 12 via a second metal plating part 32. The metal plating can be formed by, for example, electrolytic plating or electroless plating. The metal plating is, for example, copper plating or gold plating. As the metal plating, zinc (Zn), chromium (Cr), and/or nickel (Ni) may be used.

### Step of Removing Bonding Member

Next, after the step of forming the metal plating, the bonding member 70 is removed as illustrated in FIG. 2H. The removal of the bonding member 70 may be performed by immersing the bonding member 70 in a peeling solution that can peel off the bonding member 70, or may be performed by any other method. For example, a nozzle may be used to spray a given peeling solution onto the bonding member 70 within a chamber. This peeling solution allows the bonding member 70 to be dissolved, and the dissolved bonding member 70 is delivered to the outside of the base 11 by using a predetermined gas or the like.

The peeling solution may be a mixed solution containing sulfuric acid, an organic solvent, and the like. As the organic solvent, for example, at least one solvent selected from the group consisting of alcohol-based solvents such as 2-propanol, ketone-based solvents such as acetone, ester-based solvents such as ethyl acetate, and ether-based solvents can be used. Examples of the gas used to deliver the dissolved bonding member 70 include argon gas, nitrogen gas, and the like.

After the bonding member 70 is removed, a protective film 35 may be provided so as to cover a second lateral surface 31c of the first metal plating part 31 and a second lateral surface 32c of the second metal plating part 32 as illustrated in FIG. 2H. The protective film 35 can be provided by, for example, atomic layer deposition. The protective film 35 may extend from the second lateral surface 31c and the second lateral surface 32c to an outer peripheral portion of the second surface 20b and lateral surfaces 20c of the light-emitting element 20. Further, the protective film 35 may be provided on a first lateral surface 31b and a first lateral surface 32b in addition to the second lateral surface 31c and the second lateral surface 32c.

### Step of Disposing Light Reflective Member

Next, as illustrated in FIG. 2I, a light reflective member 40 is disposed on the substrate 10 as necessary. For example, an uncured white resin is disposed on the substrate 10 so as to cover a plurality of light-emitting elements 20, and the white resin is caused to flow to fill a space between facing lateral surfaces 20c of adjacent light-emitting elements 20 and spaces between second surfaces 20b of the plurality of light-emitting elements 20 and the upper surface 11a of the base 11. Thereafter, the white resin is cured to obtain the light reflective member 40. The uncured white resin can be disposed on the substrate 10 by, for example, potting, spraying, or printing. If first surfaces 20a of the plurality of light-emitting elements 20 are covered by the white resin, the first surfaces 20a are exposed by polishing or the like.

Through the above steps, the light-emitting device 1 in which the plurality of light-emitting elements 20 are mounted on the substrate 10 can be manufactured.

### Modification

In a modification, there are a plurality of first structures 110, and a step of obtaining a third structure 130 includes a step of arranging the plurality of first structures 110 on a second structure 120.

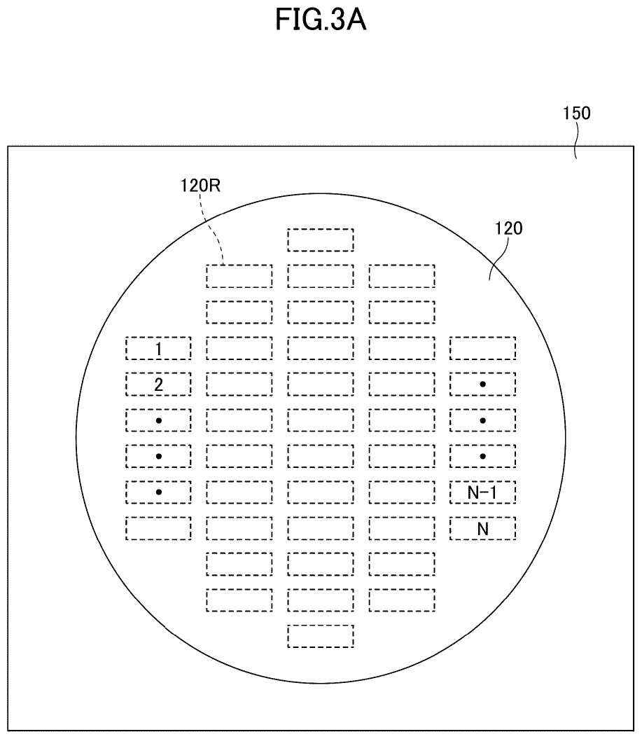

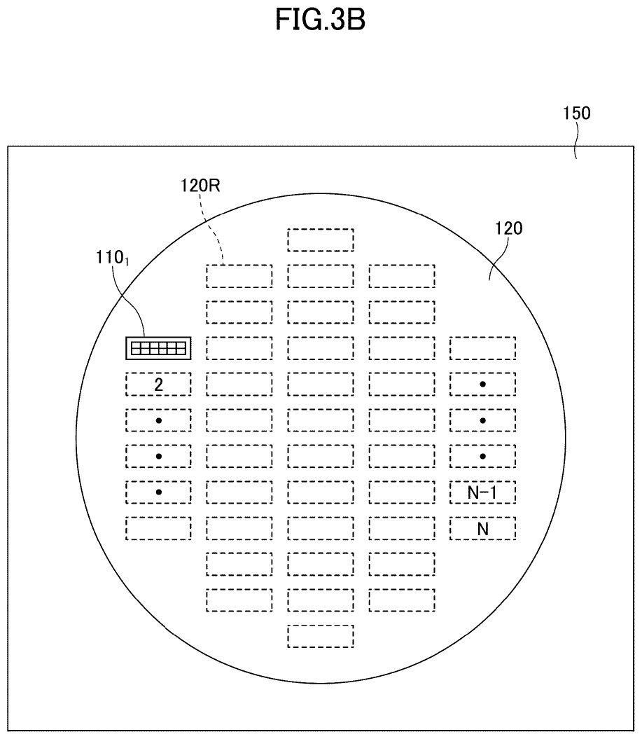

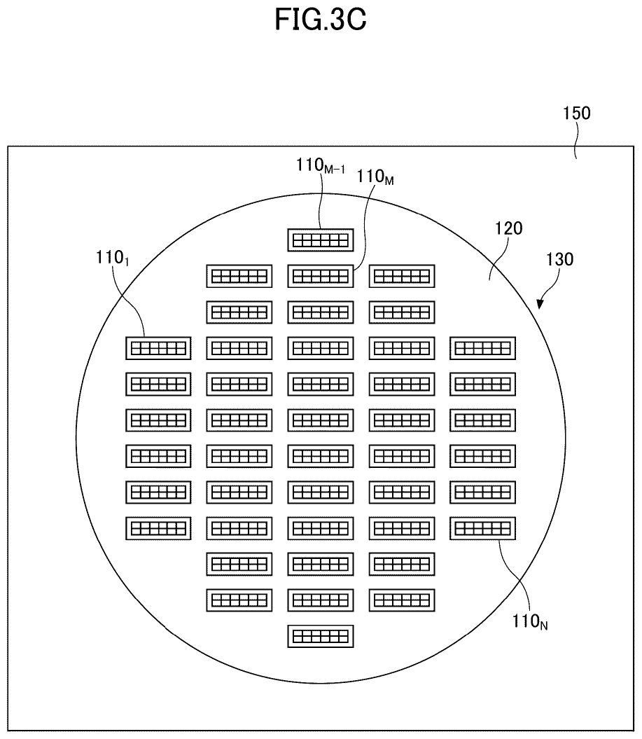

FIG. 3A to FIG. 3C are plan views schematically illustrating an example of a manufacturing process in a method of manufacturing light-emitting devices according to the modification of the embodiment, and illustrate a process of obtaining the third structure 130.

As illustrated in FIG. 3A, in the modification, the second structure 120 is a wafer including N number (N is a natural number) of regions 120R that are to be singulated into a plurality of light-emitting devices 1. The regions 120R are arranged, for example, at predetermined intervals in a matrix. Each of the regions 120R has a structure similar to the structure illustrated in FIG. 2B and FIG. 2C. That is, each of the regions 120R includes a plurality of pairs of wirings 12 and a bonding member 70. A substrate 10 is common to the N number of regions 120R. The second structure 120 is disposed on a stage 150. The stage 150 is heated to a first temperature in advance.

In the step of obtaining the third structure, N number of first structures 110 are arranged in order in the N-number of regions 120R of the second structure 120. First, as illustrated in FIG. 3B, a first structure 1101 is disposed in the first region 120R. A bonding member 70 is softened at the first temperature, and light-emitting elements 20 and the substrate 10 are bonded with the bonding member 70 interposed therebetween.

Next, as illustrated in FIG. 3C, first structures 110 are arranged in second regions 120R in order from the second region 120R, and finally, a first structure 110N is disposed in the Nth region 120R. A bonding member 70 in each of the regions 120R is softened at the first temperature, and light-emitting elements 20 and the substrate 10 are bonded to each other with the bonding member 70 interposed therebetween in each of the regions 120R. Accordingly, the third structure 130 in which the plurality of first structures 110 are arranged on the second structure 120 can be obtained.

The time taken for the N number of first structures 110 to be arranged is, for example, 0.5 hours or more and 10 hours or less. That is, the bonding member 70 in the first region 120R is bonded to the light-emitting elements 20 of the first structure 1101 substantially without waiting on the stage 150. Conversely, a bonding member 70 in the Nth region 120R is bonded to light-emitting elements 20 of the first structure 110N after waiting for 0.5 hours or more and 10 hours or less on the stage 150.

In FIG. 3C, the adhesion between the light-emitting elements 20 of the first structure 1101 disposed in the first region 120R and the bonding member 70 of the second structure 120 is high. Conversely, the adhesion between the light-emitting elements 20 of the first structure 110N disposed in the Nth region 120R and the bonding member 70 of the second structure 120 is decreased. This is because, as described above, the bonding member 70 in the Nth region 120R waits for a long period of time on the stage 150, and thus, a solvent volatilizes from the surface of the bonding member 70 and the tack strength on the surface side of the bonding member 70 decreases.

After the step illustrated in FIG. 3C, a step of heating the third structure 130 at a second temperature that is equal to or higher than the first temperature is performed. Accordingly, the adhesion between light-emitting elements 20 and bonding members 70 including the bonding member 70 in the Nth region 120R, which has decreased due to a long waiting period of time on the stage 150, can be improved as compared to the adhesion before the step of heating the third structure at the second temperature. The reason why the adhesion is improved is as described above.

Thereafter, a support substrate 50 is removed from the third structure in the same manner as in FIG. 2F. In the step of heating the third structure at the second temperature, the adhesion between light-emitting elements 20 and bonding members 70 is improved, and thus the possibility that the light-emitting elements 20 are peeled off from the bonding members 70 and taken away together with the support substrate 50 can be reduced. In the related art, the adhesion of bonding members 70 particularly in the Nth region 120R and regions close thereto is reduced, and thus, light-emitting elements 20 in these regions would be taken away together with a support substrate 50 in many cases. Conversely, according to the modification, by providing the step of heating the third structure at the second temperature, the possibility that light-emitting elements 20 in the Nth region 120R and regions close thereto may be taken away together with support substrates 50 can be reduced, similar to the other regions. In particular, as the value of N increases and the waiting time on the stage increases, it becomes more effective to provide the step of heating the third structure at the second temperature so as to improve the adhesion between light-emitting elements 20 and bonding members 70.

Thereafter, after steps similar to the steps of FIG. 2F to FIG. 2I are performed, the regions 120R are singulated by dicing or the like. As a result, N number of light-emitting devices 1 in which the plurality of light-emitting elements 20 are mounted on the substrate 10 can be manufactured.

In the step of heating the third structure at the second temperature, the Mth first structure 110M (M is a natural number of 2 or more and N or less) is heated at a temperature higher than a temperature at which the M−1th first structure 110M-1 is heated. By heating a bonding member 70, whose adhesion is further reduced, at a higher temperature, the adhesion of the bonding member 70 can be further improved.

Although embodiments have been described in detail above, the above-described embodiments are non-limiting examples, and various modifications and substitutions can be made to the above-described embodiments without departing from the scope described in the claims.

For example, in the above description, when the heating step at the second temperature is performed, the third structure is moved from the stage, used in the heating step at the first temperature, to another heating device (for example, an oven). However, in the present disclosure, after the heating step at the first temperature, the third structure may be heated at the second temperature on the same stage used in the heating step at the first temperature. Accordingly, the time required for the manufacturing process can be shortened. Conversely, by moving the third structure from the stage used in the heating step at the first temperature to another heating device (for example, an oven) when the heating step at the second temperature is performed, the operation rate of the stage can be improved, and thus mass productivity can be improved.

According to certain embodiments of the present disclosure, a method of manufacturing a light-emitting device, in which high reliability in transferring a light-emitting element is ensured, and a light-emitting device can be provided.

1. A method of manufacturing a light-emitting device, the method comprising:
preparing at least one first structure comprising:
a support substrate,
an adhesive layer disposed on a first main surface of the support substrate, and
a plurality of light-emitting elements each having a first surface and a second surface that is located on a side opposite the first surface and comprises a pair of element electrodes disposed on the second surface side, the first surface being in contact with the adhesive layer;
preparing a second structure comprising:
a substrate comprising a base, and a plurality of pairs of wirings disposed on an upper surface of the base, and
a bonding member disposed between a pair of wirings of the plurality of pairs of wirings and having a thickness greater than a thickness of each of the wirings;
obtaining a third structure by causing the pair of element electrodes of the at least one first structure to face the pair of wirings of the second structure and bonding each of the plurality of light-emitting elements to the substrate with the bonding member interposed therebetween in a state in which the plurality of light-emitting elements and the substrate are heated at a first temperature;
heating the third structure at a second temperature equal to or higher than the first temperature; and
removing the support substrate from the third structure.

2. The method of manufacturing the light-emitting device according to claim 1, wherein:
the at least one first structure comprises a plurality of first structures,
the obtaining of the third structure comprises arranging the plurality of first structures on the second structure, and
a time taken for arranging the plurality of first structures is 0.5 hours or more and 10 hours or less.

3. The method of manufacturing the light-emitting device according to claim 2, wherein:
in the obtaining of the third structure, N number of first structures are arranged in order, where N is a natural number, and
in the heating of the third structure at the second temperature, an Mth first structure is heated at a temperature higher than a temperature at which an M−1th first structure is heated, where M is a natural number of 2 or more and N or less.

4. The method of manufacturing the light-emitting device according to claim 1, further comprising:
after the removing of the support substrate, forming metal plating, wherein:
in the obtaining of the third structure, the pair of element electrodes of each of the plurality of light-emitting elements are spaced apart from the pair of wirings of the substrate, and
in the forming of the metal plating, the metal plating electrically connects the pair of element electrodes of each of the plurality of light-emitting elements to the pair of wirings of the substrate.

5. The method of manufacturing the light-emitting device according to claim 4, wherein:
the metal plating is copper plating or gold plating.

6. The method of manufacturing the light-emitting device according to claim 5, wherein:
the second temperature is 140° C. or less.

7. The method of manufacturing the light-emitting device according to claim 4, further comprising:
after the forming of the metal plating, removing the bonding member.

8. The method of manufacturing the light-emitting device according to claim 1, wherein:
in a cross-sectional view taken through the first surface and the pair of element electrodes of each of the plurality of light-emitting elements, a ratio of a width of an upper surface of the bonding member to a width of a lower surface of the bonding member after the heating of the third structure at the second temperature is 0.910 or more.

9. A light-emitting device comprising:
a substrate comprising a base, and a plurality of pairs of wirings disposed on the base;
a plurality of light-emitting elements each having a first surface and a second surface that is located on a side opposite the first surface and has a pair of element electrodes disposed on a side of the second surface, the pair of element electrodes facing a pair of wirings of the plurality of pairs of wirings; and
a first metal plating part and a second metal plating part, the first metal plating part and the second metal plating part electrically connecting the pair of element electrodes of each of the plurality of light-emitting elements to the pair of wirings, wherein
in a cross-sectional view taken through the first surface and the pair of element electrodes of each of the plurality of light-emitting elements, the first metal plating part has an upper surface in contact with the pair of element electrodes, a first lateral surface connected to one end of the upper surface and located closer to the second metal plating part, and a second lateral surface connected to another end of the upper surface and located opposite to the first lateral surface,
in the cross-sectional view, a shape of the first lateral surface differs from a shape of the second lateral surface, and
in the cross-sectional view, the first lateral surface has a projection.
